(19) United States
(12) Patent Application Publication
(10) Pub. No.: US 2007/0020537 A1
(43) Pub. Date: Jan. 25, 2007

(54) Exposure apparatus correction system, exposure apparatus correcting method, and manufacturing method of semiconductor device

(76) Inventors: Shoichi Harakawa, Yokohama-Shi (JP); Makoto Ikeda, Yokkaichi-Shi (JP); Takuya Kono, Yokosuka-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/486,033

(22) Filed: Jul. 14, 2006

(30) Foreign Application Priority Data
Jul. 15, 2005 (JP) 2005-207668

(51) Int. Cl. G03F 7/00

(52) U.S. Cl. 430/30; 430/311

(57) ABSTRACT

An exposure apparatus correction system comprising: a displacement calculator which calculates matching displacements between a first inspection pattern and a second inspection pattern, the first inspection pattern being transferred by an external first exposure apparatus, the second inspection pattern being positioned with respect to the first inspection pattern and transferred by a second exposure apparatus; an approximator which applies design coordinate systems and values of the calculated matching displacements to approximate expressions in which the matching displacements and a relationship between coordinate systems including the second inspection pattern is approximated by using a plurality of parameters, thereby allocating estimators to the plurality of respective parameters, the plurality of parameters having a mutually complementary relationship; a rounder which rounds estimators of the allocated estimators which are out of an effective range restricted by the second exposure apparatus to fall within the effective range; a back-calculator which defines the rounded estimators as new estimators and applies the new estimators and the design coordinate systems to the approximate expressions to calculate back calculation deviances which are expected to occur between the first inspection pattern and the second inspection pattern when the rounded values are used; a residual calculator which subtracts the calculation deviances from the matching displacements to obtain residuals; a corrected value calculator which utilizes the mutually complementary relationship between the plurality of parameters to calculate corrected values as values which reduce the residuals based on other parameters than the parameters whose estimators have been rounded in the plurality of parameters with respect to the other parameters; an adder which sequentially adds the new estimators and the corrected values and outputs results as a sum total of the estimators; an estimator memory which stores the sum total of the estimators; and a controller which allows the rounder, the back-calculator, the residual calculator, the corrected value calculator and the adder to cyclically perform repeated operations, and corrects the second exposure apparatus based on the sum total of the estimators stored in the estimator memory.

### CROSS REFERENCE TO RELATED APPLICATION

This application claims benefit of priority under 35 USC §119 to Japanese patent application No. 2005-207668, filed on Jul. 15, 2005, the contents of which are incorporated by reference herein.

### BACKGROUND OF THE INVENTION

1. Field of the Invention

The present invention relates to an exposure apparatus correction system, an exposure apparatus correcting method, and a manufacturing method of a semiconductor device.

2. Related Background Art

In case of manufacturing a semiconductor device having a laminated structure, there is carried out a lithography process which transfers a pattern onto each layer in the laminated structure by using an exposure apparatus. In order to manufacture a highly accurate semiconductor device, patterns transferred on the respective layers must overlap in the same plane region. However, when a series of manufacturing processes advances with different exposure apparatuses, shot shapes of patterns transferred on the respective layers do not become equal to each other due to an accuracy error of each exposure apparatus in some cases. Therefore, the lithography process has adopted a correction technology which eliminates a “matching displacement” of a first inspection pattern transferred on a lower layer and a second inspection pattern transferred on an upper layer (see, e.g., Japanese Patent Laid-open No. 2001-338860). In a conventional correction technology, on the assumption that first and second inspection patterns are transferred in a plane in which an x-y coordination system is defined, a relationship between a coordinate system (x, y) and a matching displacement ex in an x direction and a matching displacement e_{y} in a y direction of the first and second inspection patterns in the coordinate system (x, y) is approximated by using the following Expressions (1) and (2).
eₓ=k₁+k₃x+k₅y (1)
e_{y}=k₂+k₄y+k₆x (2)

An accuracy error of each exposure apparatus can be corrected based on a least-squares estimator (which will be referred to as an estimator hereinafter) of each of parameters k₁ to k₆ in Expressions (1) and (2). However, with advancement of miniaturization of a semiconductor device, correction of the exposure apparatus cannot be sufficiently performed based on only the parameters k₁ to k₆ used in a primary approximate function like those in Expressions (1) and (2). Therefore, a method which approximates the coordinate system (x, y) and the displacements eₓ and e_{y} by using a higher-order approximate function like the following Expressions (3) and (4) has been recently adopted.
eₓ=k₁+k₃x+k₅y+k₇x²+k₉xy+k₁₁y²+k₁₃x³+k₁₅x²y+k₁₇xy²+k¹⁹y³ (3)
ey=k₂+k₄y+k₆x+k₈y²+k₁₀xy+k₁₂x²+k₁₄y³+k₁₆xy²+k₁₈x²y+k₂₀x³ (4)

Here, an accuracy error of an optical system in the exposure apparatus can be corrected based on an estimator of each of parameters k₇ to k₂₀ concerning second- or higher-order terms in Expressions (3) and (4). However, correction of the optical system is effective for skew correction of shot shapes of the first and second inspection patterns, whereas it involves a side effect such as defocusing or a fluctuation in aberration. Therefore, when each exposure apparatus is corrected by using an estimator of each of the parameters k₇ to k₂₀ in Expressions (3) and (4) as it is, there is a problem that a transfer accuracy of the second inspection pattern is lowered.

### SUMMARY OF THE INVENTION

According to a first aspect of the invention, there is provided an exposure apparatus correction system comprising:

a displacement calculator which calculates matching displacements between a first inspection pattern and a second inspection pattern, the first inspection pattern being transferred by an external first exposure apparatus, the second inspection pattern being positioned with respect to the first inspection pattern and transferred by a second exposure apparatus;

an approximator which applies design coordinate systems and values of the calculated matching displacements to approximate expressions in which the matching displacements and a relationship between coordinate systems including the second inspection pattern is approximated by using a plurality of parameters, thereby allocating estimators to the plurality of respective parameters, the plurality of parameters having a mutually complementary relationship;

a rounder which rounds estimators of the allocated estimators which are out of an effective range restricted by the second exposure apparatus to fall within the effective range;

a back-calculator which defines the rounded estimators as new estimators and applies the new estimators and the design coordinate systems to the approximate expressions to calculate back calculation deviances which are expected to occur between the first inspection pattern and the second inspection pattern when the rounded values are used;

a residual calculator which subtracts the calculation deviances from the matching displacements to obtain residuals;

a corrected value calculator which utilizes the mutually complementary relationship between the plurality of parameters to calculate corrected values as values which reduce the residuals based on other parameters than the parameters whose estimators have been rounded in the plurality of parameters with respect to the other parameters;

an adder which sequentially adds the new estimators and the corrected values and outputs results as a sum total of the estimators;

an estimator memory which stores the sum total of the estimators; and

a controller which allows the rounder, the back-calculator, the residual calculator, the corrected value calculator and the adder to cyclically perform repeated operations, and corrects the second exposure apparatus based on the sum total of the estimators stored in the estimator memory.

According to a second aspect of the invention, there is provided an exposure apparatus correcting method comprising:

calculating matching displacements between a first inspection pattern and a second inspection pattern, the first inspection pattern being transferred by a first exposure apparatus with design coordinate systems on a first inspection wafer being determined as targets, the second inspection pattern being positioned with respect to the first inspection pattern and transferred by a second exposure apparatus with the design coordinate systems on a second inspection wafer being determined as targets;

applying the design coordinate systems and values of the calculated matching displacements to approximate expressions in which a relationship between the matching displacements and coordinate systems including the second inspection pattern is approximated by using a plurality of parameters to allocate estimators to the plurality of parameters, the plurality of parameters having a mutually complementary relationship;

rounding estimators of the allocated estimators which are out of an effective range restricted by the second exposure apparatus to fall within the effective range;

defining the rounded estimators as new estimators and applying the new estimators and the design coordinate systems to the approximate expressions to calculate back calculation deviances which are expected to occur between the first inspection pattern and the second inspection pattern when the rounded values are used;

subtracting the calculation deviances from the matching displacements to obtain residuals;

utilizing the mutually complementary relationship between the plurality of parameters to calculate corrected values as values which reduce the residuals based on other parameters than the parameters whose estimators have been rounded with respect to the other parameters;

sequentially adding the new estimators and the corrected values and outputting a result as a sum total of the estimators; and

repeating the rounding, the back calculation, the calculation of the residuals, the calculation of the corrected values and the sequential addition to correct the second exposure apparatus based on the sum total of the estimators.

According to a third aspect of the invention, there is provided a manufacturing method of a semiconductor device, comprising:

coating a processing target substrate with a first resist;

transferring a first product pattern onto the first resist by using a first exposure apparatus;

processing the processing target substrate with the first product pattern being used as a mask;

calculating matching displacements between the first inspection pattern and the second inspection pattern, the first inspection pattern being transferred by the first exposure apparatus with design coordinate systems on a first inspection wafer being determined as targets, the second inspection pattern being positioned with respect to the first inspection pattern and transferred by a second exposure apparatus with the design coordinate systems on a second inspection wafer being determined as targets;

applying the design coordinate systems and values of the calculated matching displacements to approximate expressions in which a relationship between the matching displacements and coordinate systems including the second inspection pattern is approximated by using a plurality of parameters to allocate estimators to the plurality of parameters, the plurality of parameters having a mutually complementary relationship;

rounding estimators of the allocated estimators which are out of an effective range restricted by the second exposure apparatus to fall within the effective range;

defining the rounded estimators as new estimators and applying the new estimators and the design coordinate systems to the approximate expressions to calculate back calculation deviances which are expected to occur between the first inspection pattern and the second inspection pattern when the rounded values are used;

subtracting the calculation deviances from the matching displacements to obtain residuals;

utilizing the mutually complementary relationship between the plurality of parameters to calculate corrected values as values which reduce the residuals based on other parameters than the parameters whose estimators have been rounded with respect to the other parameters;

sequentially adding the new estimators and the corrected values and outputting a result as a sum total of the estimators;

repeating the rounding, the back calculation, the calculation of the residuals, the calculation of the corrected values, and the sequentially addition to correct the second exposure apparatus based on the sum total of the estimators;

coating the processing target substrate with a second resist;

positioning a second product pattern with respect to the first product pattern and transferring the same onto the second resist by using the corrected second exposure apparatus; and

processing the processing target substrate with the second product pattern being used as a mask.

### BRIEF DESCRIPTION OF THE DRAWINGS

FIG. 1 is a block diagram showing an exposure apparatus correction system according to an embodiment of the present invention;

FIG. 2 is a schematic view showing a first exposure apparatus provided in the exposure apparatus correction system depicted in FIG. 1;

FIG. 3 is a schematic view showing lens elements in the first exposure apparatus depicted in FIG. 2;

FIG. 4 is a top view showing a first shot shape obtained by the first exposure apparatus depicted in FIG. 2;

FIG. 5 is a top view showing a second shot shape obtained by a second exposure apparatus provided in the exposure apparatus correction system depicted in FIG. 1;

FIG. 6 is a schematic view showing a matching displacement between the first shot shape and the second shot shape depicted in FIGS. 4 and 5, respectively;

FIG. 7 shows an example of a measurement value table in which the matching displacement depicted in FIG. 6 is recorded;

FIG. 8 shows an example of a parameter master which records parameters which are available for use in the second exposure apparatus provided in the exposure apparatus correction system depicted in FIG. 1;

FIG. 9 shows an example of a parameter master which records effective ranges of parameters which are available for use in the second exposure apparatus provided in the exposure apparatus correction system depicted in FIG. 1;

FIG. 10 shows an example of a working table which records an estimator of each parameter according to an embodiment of the present invention;

FIG. 11 shows an example of a working table which records a corrected value of each parameter according to an embodiment of the present invention;

FIG. 12 shows an example of a working table which records a flag given to each parameter according to an embodiment of the present invention;

FIG. 13 is a flowchart showing an exposure apparatus correcting method according to an embodiment of the present invention; and

FIG. 14 is a flowchart showing a manufacturing method of a semiconductor device according to an embodiment of the present invention.

### DETAILED DESCRIPTION OF THE INVENTION

An embodiment according to the present invention will now be described hereinafter with reference to the accompanying drawings. In the drawings, like reference numerals denote like or corresponding parts. It is to be noted that the following embodiment exemplifies an apparatus or a method which embodies a technical concept of the present invention, and the technical concept of the present invention does not restrict constituent components or arrangements to those described below. The technical concept of the present invention can be changed in many ways within the scope of claims.

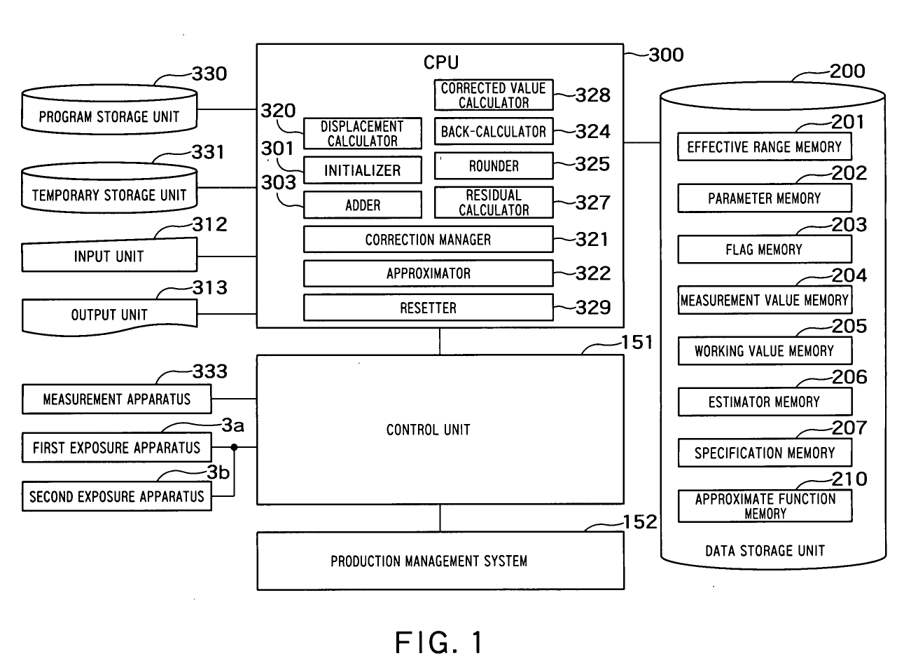

As shown in FIG. 1, an exposure apparatus correction system according to an embodiment is provided with a measurement apparatus 333 which can be connected to an external first exposure apparatus 3a and an external second exposure apparatus 3b and measures a first inspection pattern transferred on a first inspection wafer and a second inspection pattern positioned with respect to the first inspection pattern and transferred on a second inspection wafer, and a central processing unit (CPU) 300. The CPU 300 includes a displacement calculator 320, an approximator 322, a rounder 325, a back-calculator 324, a residual calculator 327, a corrected value calculator 328, and an adder 303. A data storage unit 200 is connected with the CPU 300, and the data storage unit 200 has an estimator memory 206.

The displacement calculator 320 calculates each matching displacement of the first inspection pattern and the second inspection pattern. The approximator 322 applies a design coordinate system and a value of the matching displacement to the approximate expressions (3) and (4) which approximate a relationship between a coordinate system including the second inspection pattern and the matching displacement by using a plurality of parameters, thereby allocating an estimator to each of the plurality of parameters. The rounder 325 executes processing of rounding an estimator of the allocated estimators which is out of an effective range restricted by the second exposure apparatus by which the second inspection pattern has been transferred to fall within this effective range. The back-calculator 324 defines the rounded value as a new estimator, applies the new estimator and the design coordinate system to the approximate expressions, and calculates back a calculation deviance which is expected to occur between the first inspection pattern and the second inspection pattern when the rounded value is used. The residual calculator 327 subtracts the calculation deviance from the matching displacement, thereby obtaining a residual. The corrected value calculator 328 utilizes a mutually complementary relationship between the plurality of parameters to obtain a corrected value as a value which reduces the residual by using a parameter other than the parameter having the rounded estimator with respect to the other parameter. The adder 303 sequentially adds the new estimator and the corrected value and stores a result as a sum total of the estimators in the estimator memory 206. The estimator memory 206 stores the sum total of the estimators added by the adder 303. A control unit 151 is connected with the CPU 300. The control unit 151 allows the rounder 325, the back-calculator 324, the residual calculator 327, the corrected value calculator 328 and the adder 303 to cyclically perform repetitive operations, and thereby corrects an optical system or the like in the second exposure apparatus 3b based on the sum total of the estimators stored in the estimator memory 206, thereby reducing the matching displacement. The first exposure apparatus 3a and the second exposure apparatus 3b are connected with the control unit 151.

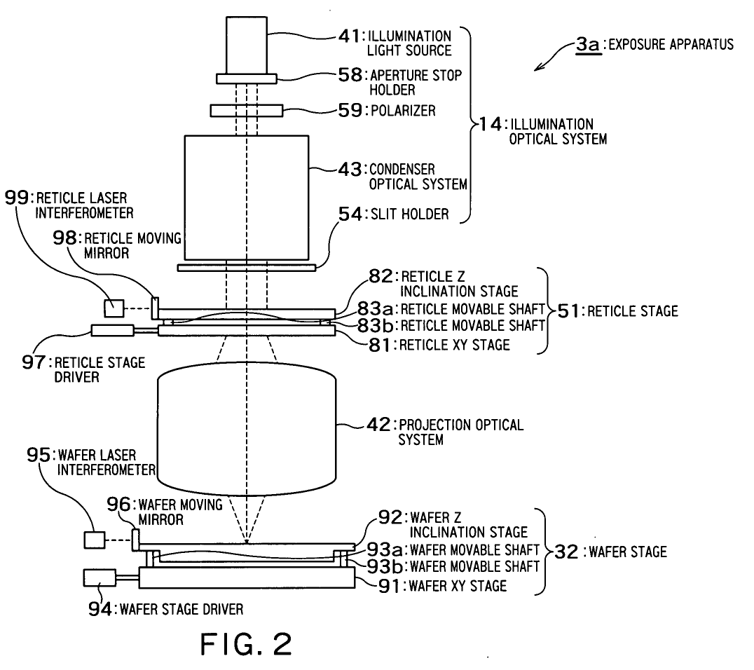

As shown in FIG. 2, the first exposure apparatus 3a has an illumination optical system 14. The illumination optical system 14 has an illumination light source 41 such as an argon fluoride laser having a wavelength of 193 nm which emits illumination light, an aperture stop holder 58 arranged below the illumination light source 41, a polarizer 59 which polarizes the illumination light emitted from the illumination light source 41, an condenser optical system 43 which condenses the illumination light, and a slit holder 54 arranged below the condenser optical system 43. The first exposure apparatus 3a is further provided with a reticle stage 51 arranged below the slit holder 54, a projection optical system 42 arranged below the reticle stage 51, and a wafer stage 32 arranged below the projection optical system 42. A polarizer adjustment mechanism (not shown) is connected with the polarizer 59. The polarizer adjustment mechanism (not shown) adjusts an arrangement position of the polarizer 59 to regulate a polarizing direction of the illumination light.

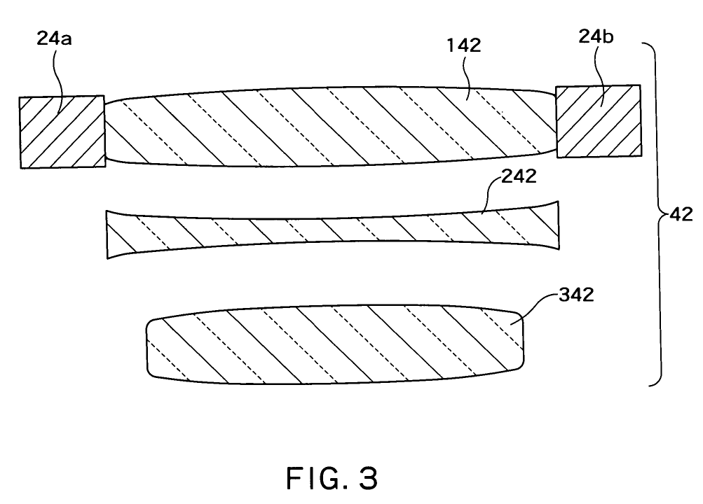

As shown in FIG. 3, the projection optical system 42 includes lens elements 142, 242 and 342. Here, lens drivers 24a and 24b such as piezoelectric elements are connected with the lens element 142. Each lens driver 24a or 24b is independently controlled by a drive voltage applied thereto, and inclines the lens element 142 at an arbitrary angle with respect to a plane perpendicular to an optical axis or moves the lens element 142 in an optical axis direction.

The reticle stage 51 shown in FIG. 2 is provided with a reticle XY stage 81, reticle movable shafts 83a and 83b arranged on the reticle XY stage 81, and a reticle Z inclination stage 82 connected with the reticle XY stage 81 through the respective reticle movable shafts 83a and 83b. A reticle stage driver 97 is connected with the reticle stage 51. The reticle stage driver 97 scans the reticle XY stage 81 in a horizontal direction. Further, the reticle stage driver 97 drives each of the reticle movable shafts 83a and 83b in a vertical direction. Therefore, the reticle Z inclination stage 82 is positioned in the horizontal direction by the reticle XY stage 81, and it can be inclined and arranged with respect to a horizontal plane by each of the reticle movable shafts 83a and 83b. A reticle moving mirror 98 is arranged at an end portion of the reticle Z inclination stage 82. An arrangement position of the reticle Z inclination stage 82 is measured by a reticle laser interferometer 99 arranged to face the reticle moving mirror 98.

The wafer stage 32 is provided with a wafer XY stage 91, wafer movable shafts 93a and 93b arranged on the wafer XY stage 91, and a wafer Z inclination stage 92 connected with the wafer XY stage 91 through the respective wafer movable shafts 93a and 93b. A wafer stage driver 94 is connected with the wafer stage 32. The wafer stage driver 94 scans the wafer XY stage 91 in the horizontal direction. Furthermore, the wafer stage driver 94 drives each of the wafer movable shafts 93a and 93b in the vertical direction. Therefore, the wafer Z inclination stage 92 is positioned in the horizontal direction by the wafer XY stage 91, and it can be inclined and arranged with respect to a horizontal plane by each of the wafer movable shafts 93a and 93b. A wafer moving mirror 96 is arranged at an end portion of the wafer Z inclination stage 92. An arrangement position of the wafer Z inclination stage 92 is measured by a wafer laser interferometer 95 arranged to face the wafer moving mirror 96. It is to be noted that the second exposure apparatus 3b shown in FIG. 1 also has the same structure as that of the first exposure apparatus 3a depicted in FIG. 3.

As the measurement apparatus 333 shown in FIG. 1, it is possible to use, e.g., an optical microscope, a scanning electron microscope (SEM), an atom force microscope (AFM) and others. The measurement apparatus 333 uses the first exposure apparatus 3a to measure first coordinate systems (xₐ₁, yₐ₁), (xₐ₂, yₐ₂), (xₐ₃, yₐ₃), . . . , (xₐₙ, yₐₙ) on the first inspection wafer 15 where first inspection patterns 45a, 45b, 45c, . . . , 45n have been actually transferred, the first inspection patterns having been transferred with a plurality of design coordinate systems (x_{D1}, y_{D1}), (x_{D2}, y_{D2}), (x_{D3}, y_{D3}), . . . , (x_{Dn}, y_{Dn}) on the first inspection wafer 15 determined as targets. Here, a shape and a size of each of the first inspection patterns 45a, 45b, 45c, . . . , 15n are arbitrary, and it is possible to use a circular or rectangular inspection pattern or an arbitrary semiconductor integrated circuit pattern. Moreover, the measurement apparatus 333 uses the second exposure apparatus 3b to measure second coordinate systems (x_{b1}, y_{b1}), (x_{b2}, y_{b2}), (x_{b3}, y_{b3}), . . . , (x_{bn}, y_{bn}) on the second inspection pattern 115 where second inspection patterns 154a, 145b, 145c, . . . , 145n have been actually transferred, the second inspection patterns having been transferred with design coordinate systems (x_{D1}, y_{D1}), (x_{D2}, y_{D2}), (x_{D3}, y_{D3}), . . . , (x_{Dn1}, y_{Dn}) on the second inspection wafer 115 determined as targets. Each of the second inspection patterns 145a, 145b, 145c, . . . , 145n also has an arbitrary shape and an arbitrary size, and it may have the same shape as that of each of the first inspection patterns 45a, 45b, 45c, . . . , 45n.

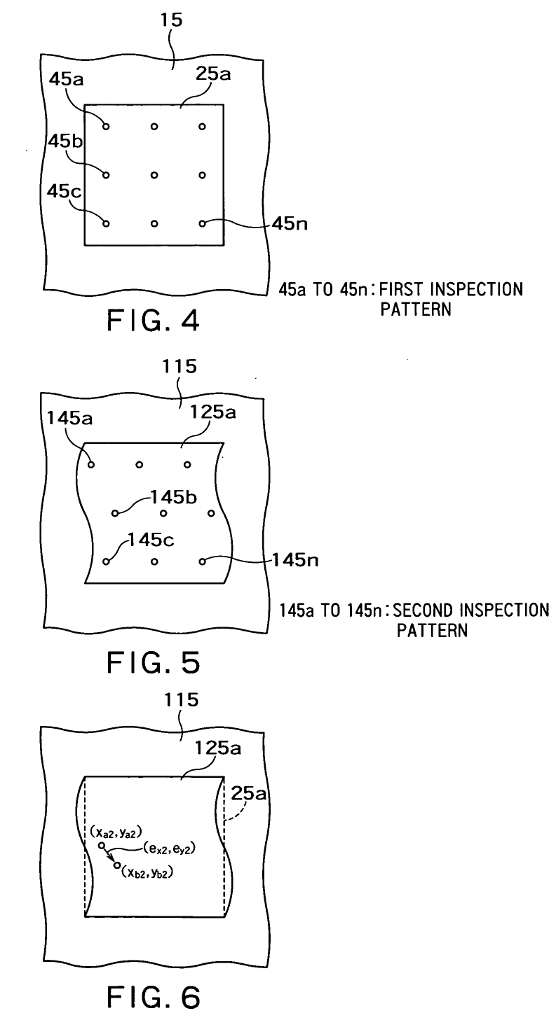

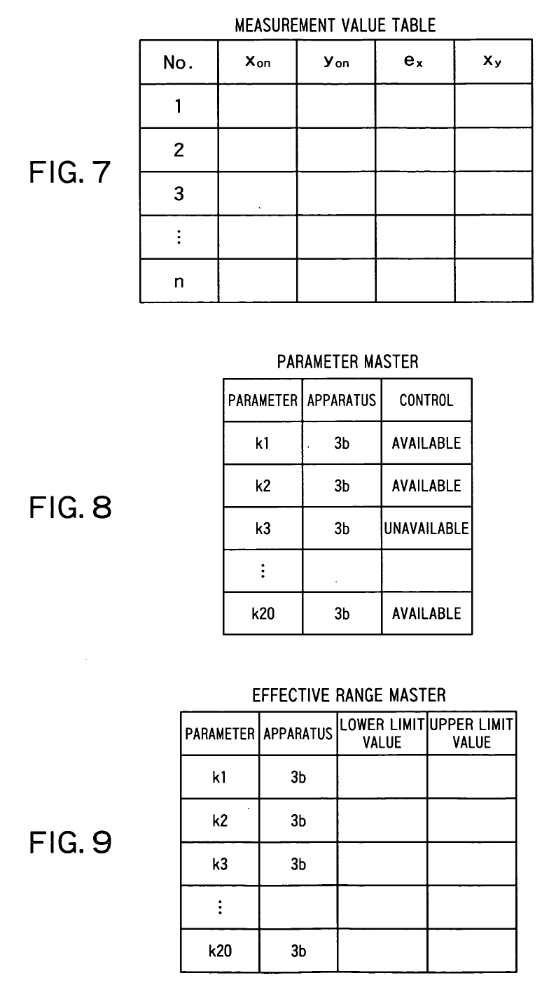

As shown in FIGS. 4 and 5, a first shot shape 25a on the first inspection wafer 15 is different from a second shot shape 125a on the second inspection wafer 115 due to an inter-apparatus error between the first exposure apparatus 3a and the second exposure apparatus 3b. The displacement calculator 320 in the CPU 300 shown in FIG. 1 subtracts each of the first coordinate systems (xₐ₁, yₐ₁), (xₐ₂, yₐ₂), (xₐ₃, yₐ₃), . . . , (xₐₙ, yₐₙ) from each of the second coordinate systems (x_{b1}, y_{b1}), (x_{b2}, y_{b2}), (x_{b3}, y_{b3}), . . . , (x_{bn}, y_{bn}) to calculate each of matching displacements (eₓ₁, e_{y1}), (eₓ₂, e_{y2}), (eₓ₃, e_{y3}), . . . , (eₓₙ, e_{yn}). FIG. 6 shows a matching displacement (eₓ₂, e_{y2}) obtained by subtracting the first coordinate system (xₐ₂, yₐ₂) from the second coordinate system (eₓ₂, e_{y2}) as an example. Additionally, the displacement calculator 320 generates a measurement value table which is a table in which the design coordinate systems (x_{D1}, y_{D1}), (x_{D2}, y_{D2}), (x_{D3}, y_{D3}), . . . , (x_{Dn}, y_{Dn}) are combined with the matching displacements (eₓ₁, e_{y1}), (eₓ₂, e_{y2}), (eₓ₃, e_{y3}), . . . , (eₓₙ, e_{yn}), respectively. FIG. 7 shows an example of the generated measurement value table.

The CPU 300 shown in FIG. 1 further has a correction manager 321 and an initializer 301. The correction manager 321 judges whether each of the plurality of (71) parameters k₁, k₂, k₃, . . . , k₂₀ in Expressions (3) and (4) is “available” or “unavailable” for correction of the second exposure apparatus 3b. For example, when the second exposure apparatus 3b does not have an aberration correcting mechanism which corrects a Seidel aberration or a Zernike aberration but the wafer stage 32 can be driven and a wavelength of light emitted from the illumination light source 41 can be changed, the correction manager 321 determines that the parameters k₇ and k₁₂ are “unavailable” and the parameter k₁₀ is “available”. Based on a result of the judgment, the correction manager 321 generates a parameter master shown in FIG. 8 in which whether each of the plurality of parameters k₁, k₂, k₃, . . . , k₂₀ is “available” or “unavailable” for correction of the second exposure apparatus 3b is recorded. Further, the correction manager 321 shown in FIG. 1 generates an effective range master in which an upper limit value and a lower limit value of each of the parameters k₁, k₂, k₃, . . . , k₂₀ defined by a restriction of a driving enabled range or the like of the reticle stage driver 97, the reticle movable shafts 83a and 83b, the wafer stage driver 94, the wafer movable shafts 93a and 93b of the second exposure apparatus 3b shown in FIG. 2 and the lens drivers 24a and 24b shown in FIG. 3 and others. FIG. 9 shows an example of the generated effective range master.

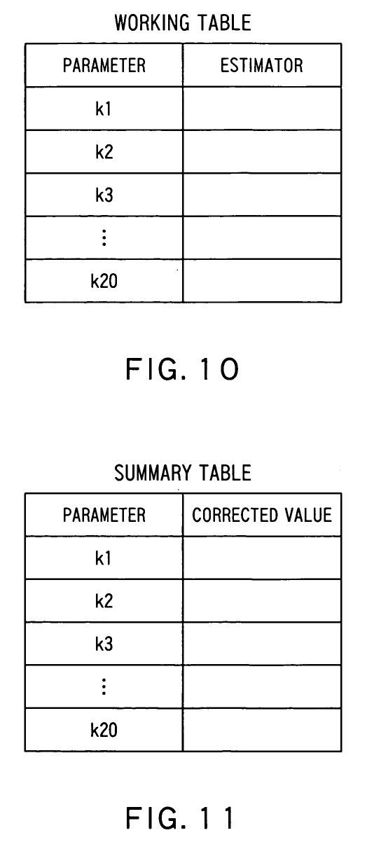

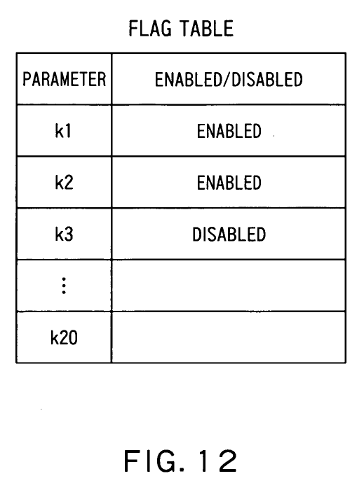

The initializer 301 shown in FIG. 1 generates a working table which records an “estimator” of each of the parameters k₁, k₂, k₃, . . . , k₂₀. FIG. 10 shows an example of the generated working table. Initial values of the “estimators” of the parameters k₁, k₂, k₃, . . . , k₂₀ are all set to 0. Furthermore, the initializer 301 shown in FIG. 1 produces a summary table depicted in FIG. 11 in which a “corrected value” of each of the parameters k₁, k₂, k₃, . . . , k₂₀ is recorded. It is to be noted that initial values of the “corrected values” of the parameters k₁, k₂, k₃, . . . , k₂₀ are all set to 0. Moreover, the initializer 301 shown in FIG. 1 generates a flag table which records whether each of the parameters k₁, k₂, k₃, . . . , k₂₀ is “enabled” or “disabled” as a processing target of the approximator 322. FIG. 12 shows an example of the generated flag table. It is to be noted that, of the parameters k₁, k₂, k₃, . . . , k₂₀, an initial setting of a parameter determined as “available” by the correction manager 321 is “enabled” and an initial setting of a parameter determined as “unavailable” by the same is “disabled”.

The approximator 322 shown in FIG. 1 uses parameters having the “enabled” flag in the flag table depicted in FIG. 12 of the parameters k₇ to k₂₀ to apply the design coordinate systems (x_{D1}, y_{D1}), (x_{D2}, y_{D2}), (x_{D3}, y_{D3}), . . . , (x_{Dn}, y_{Dn}) and the matching displacements (eₓ₁, e_{y1}), (eₓ₂, e_{y2}), (eₓ₃, e_{y3}), . . . , (eₓₙ, e_{yn}) to the approximate expressions (3) and (4), and thereby allocates an estimator to each of the parameters k₁, k₂, k₃, . . . , k₂₀. Additionally, the approximator 322 registers a value of each allocated estimator in the working table shown in FIG. 10.

The rounder 325 shown in FIG. 1 judges whether a value of the “estimator” of each of the parameters k₁, k₂, k₃, . . . , k₂₀ falls within an effective range which is not smaller than the “upper limit value” and not greater than the “lower limit value” registered in the effective range master depicted in FIG. 9. The rounder 325 shown in FIG. 1 rounds a value of the “estimator” of each of the parameters k₁, k₂, k₃, . . . , k₂₀ registered in the working table depicted in FIG. 10 which is larger than the “upper limit value” to the same value as the “upper limit value”, and reregisters the rounded value as the “estimator” in the working table. Further, the rounder 325 shown in FIG. 1 rounds a value of the “estimator” of each of the parameters k₁, k₂, k₃, . . . , k₂₀ registered in the working table depicted in FIG. 10 which is smaller than the “lower limit value” to the same value as the “lower limit value”, and reregisters the rounded value as the “estimator” in the working table.

The back-calculator 324 shown in FIG. 1 assigns the “estimator” of each of the parameters k₁, k₂, k₃, . . . , k₂₀ registered in the working table depicted in FIG. 10 to Expressions (3) and (4). Furthermore, the back-calculator 324 shown in FIG. 1 assigns each of the design coordinate systems (x_{D1}, y_{D1}), (x_{D2}, y_{D2}), (x_{D3}, y_{D3}), . . . , (x_{Dn}, y_{Dn}) to Expressions (3) and (4), and calculates back calculation deviances (hₓ₁, h_{y1}), (hₓ₂, h_{y2}), (hₓ₃, h_{y3}), ..., (hₓₙ, h_{yn}) which are expected to occur between the first inspection pattern and the second inspection pattern when the rounded values are used. The residual calculator 327 subtracts the calculation deviances (hₓ₁, h_{y1}), (hₓ₂, h_{y2}), (hₓ₃, h_{y3}), . . . , (hₓₙ, h_{yn}) from the matching displacements (eₓ₁, e_{y1}), (eₓ₂, e_{y2}), (eₓ₃, e_{y3}), . . . , (eₓₙ, e_{yn}) registered in the measurement value table depicted in FIG. 7, respectively.

The adder 303 shown in FIG. 1 adds the “estimators” of the parameters k₁, k₂, k₃, . . . , k₂₀ registered in the working table depicted in FIG. 10 to the “corrected values” of the parameters k₁, k₂, k₃, . . . , k₂₀ registered in the summary table illustrated in FIG. 11, respectively. Therefore, each of the “corrected values” of the parameters k₁, k₂, k₃, . . . , k₂₀ is equal to a sum total of each of the “estimators” of the parameters k₁, k₂, k₃, . . . , k₂₀.

The CPU 300 shown in FIG. 1 further has a resetter 329. The resetter 329 subtracts each of the “estimators” of the parameters k₁, k₂, k₃, . . . , k₂₀ from each of the “upper limit values” of the parameters k₁, k₂, k₃, . . . , k₂₀ registered in the effective range master depicted in FIG. 9 when the adder 303 has executed the addition. Likewise, the resetter 329 subtracts each of the “estimators” of the parameters k₁, k₂, k₃, . . . , k₂₀ from each of the “lower limit values” of the parameters k₁, k₂, k₃, . . . , k₂₀. Furthermore, the resetter 329 shown in FIG. 1 initializes each of the “estimators” of the parameters k₁, k₂, k₃, . . . , k₂₀ registered in the working table depicted in FIG. 10, whereby each estimator is set to 0. Moreover, the resetter 329 changes a flag of each parameter whose “estimator” has been rounded by the rounder 325 among the parameters k₁, k₂, k₃, . . . , k₂₀ from “enabled” to “disabled”, the flag being stored in the flag table depicted in FIG. 12.

The control unit 151 shown in FIG. 1 sets an exposure environment which meets exposure conditions of each of the first and second exposure apparatuses 3a and 3b. For example, it adjusts an irradiation amount of illumination light emitted from the illumination light source 41 depicted in FIG. 2. Additionally, the control unit 151 drives the reticle stage driver 97 and the wafer stage driver 94 to move the reticle stage 51 and the wafer stage 32, and uses the reticle laser interferometer 99 and the wafer laser interferometer 95 to monitor an arrangement position, a scanning direction, a scanning speed and others of each stage, thereby setting a step-and-scan exposure environment. Further, the control unit 151 shown in FIG. 1 drives the reticle stage driver 97, the reticle movable shafts 83a and 83b, the wafer stage driver 94, the wafer movable shafts 93a and 93b, and the lens drivers 24a and 24b shown in FIG. 3 and others based on the “corrected value” of each of the plurality of parameters k₁, k₂, k₃, . . . , k₂₀ registered in the summary table shown in FIG. 11, thus reducing the matching displacements. A production management system 152 is connected with the control unit 151 shown in FIG. 1. The production management system 152 supplies an apparatus processing start instruction for the first and second exposure apparatuses 3a and 3b and others to the control unit 151.

The data storage unit 200 further has a specification memory 207, an approximate function memory 210, a measurement value memory 204, a parameter memory 202, an effective range memory 201, a working value memory 205, and a flag memory 203. The specification memory 207 shown in FIG. 1 stores a specification of each of the first and second exposure apparatuses 3a and 3b. The “specification” includes driving enabled ranges of the reticle stage driver 97, the reticle stage movable shafts 83a and 83b, the wafer stage driver 94 and the wafer movable shafts 93a and 93b shown in FIG. 2, and the lens drivers 24a and 24b depicted in FIG. 3 and others. The approximate function memory 210 depicted in FIG. 1 stores approximate functions shown in Expressions (3) and (4). The measurement value memory 204 stores the measurement value table depicted in FIG. 7. The parameter memory 202 shown in FIG. 1 stores the parameter master depicted in FIG. 8. The effective range memory 201 shown in FIG. 1 stores the effective range master depicted in FIG. 9. The working value memory 205 shown in FIG. 1 stores the working table depicted in FIG. 10. The estimator memory 206 shown in FIG. 1 stores the summary table depicted in FIG. 11. The flag memory 203 shown in FIG. 1 stores the flag table depicted in FIG. 12.

To the CPU 300 are further connected an input unit 312, an output unit 313, a program storage unit 330 and a temporary storage unit 331. As the input unit 312, it is possible to use a pointing device or the like such as a keyboard or a mouse. As the output unit 313, it is possible to use an image display unit such as a liquid crystal display or a monitor, and a printer or the like. The program storage unit 330 stores an operating system or the like which controls the CPU 300. The temporary storage unit 331 sequentially stores calculation results obtained by the CPU 300. As the program storage unit 330 and the temporary storage unit 331, it is possible to use, e.g., a recording medium which records a program such as a semiconductor memory, a magnetic disk, an optical disk, a magneto optical disk or a magnetic tape.

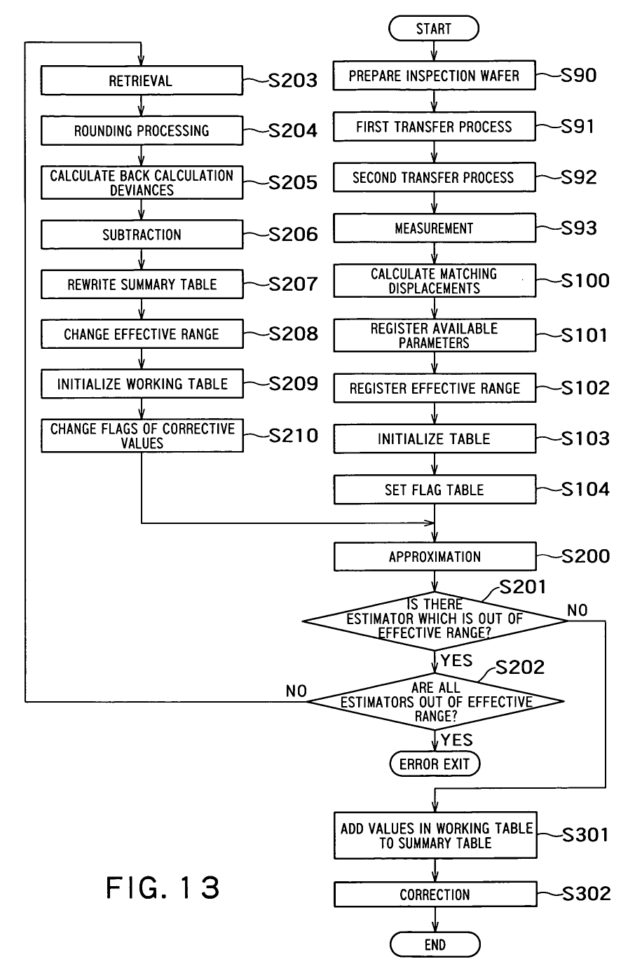

An exposure apparatus correcting method according to an embodiment will now be described with reference to a flowchart shown in FIG. 13.

(a) At a step S90, an upper side of the first inspection wafer 15 shown in FIG. 4 is spin-coated with a first inspection resist, and an upper side of the second inspection wafer 115 depicted in FIG. 5 is spin-coated with a second inspection resist. A silicon (Si) wafer or the like can be used as each of the first and second inspection wafers 15 and 115. A photosensitive agent such as a positive type or negative type photoresist can be used as each of the first and second inspection resists. It is to be noted that the equivalent photosensitive agent is used as each of the first and second inspection resists.

(b) In a first transfer process at a step S91, the first exposure apparatus 3a shown in FIGS. 1 and 2 is used to transfer each of the first inspection patterns 45a to 45n onto the first inspection resist on the first inspection wafer 15 as shown in FIG. 4. After the first inspection resist is subjected to post exposure bake (PEB) processing, the first inspection resist is developed. In design, the respective first inspection patterns 45a to 45n are respectively transferred onto the design coordinate systems (x_{D1}, y_{D1}), (x_{D2}, y_{D2}), (x_{D3}, y_{D3}), . . . , (x_{Dn}, y_{Dn}) on the first inspection wafer 15. In a second transfer process at a step S92, the second exposure apparatus 3b is used to transfer the second inspection patterns 145a to 145n onto the second inspection resist on the second wafer 115 as shown in FIG. 5, respectively. After the second inspection resist is subjected to post exposure bake (PEB) processing, the second inspection resist is developed. In design, the second inspection patterns 145a to 145n are respectively transferred onto the design coordinates (x_{D1}, y_{D1}), (x_{D2}, y_{D2}), (x_{D3}, x_{D3}), . . . , (x_{Dn}, y_{Dn}) on the second inspection wafer 115.

(c) At a step S93, in FIG. 4, the measurement apparatus 333 is used to measure the first coordinate systems (xₐ₁, yₐ₁), (xₐ₂, yₐ₂), (xₐ₃, yₐ₃), . . . , (xₐₙ, yₐₙ) on the first inspection wafer 15 where the first inspection patterns 45a to 45n have been actually transferred, the first inspection patterns 45a to 45n having been respectively transferred with the design coordinate systems (x_{D1}, y_{D1}), (x_{D2}, y_{D2}), (x_{D3}, y_{D3}), . . . , (x_{Dn}, y_{Dn}) on the first inspection wafer 15 being determined as targets. Then, in FIG. 5, the measurement apparatus 333 is used to measure the second coordinate systems (x_{b1}, y_{b1}), (x_{b2}, y_{b2}), (x_{b3}, y_{b3}), . . . , (x_{bn}, y_{bn}) on the second inspection wafer 115 where the second inspection patterns 145a to 145n have been actually transferred, the second inspection patterns 145a to 145n having been respectively transferred with the design coordinate systems (x_{D1}, y_{D1}), (x_{D2}, y_{D2}), (x_{D3}, y_{D3}), . . . , (x_{Dn}, y_{Dn}) on the second inspection wafer 115 being determined as targets.

(d) At a step S100, the displacement calculator 320 subtracts the first coordinate systems (xₐ₁, yₐ₁), (xₐ₂, yₐ₂), (xₐ₃, yₐ₃), . . . , (xₐₙ, yₐₙ) from the second coordinate systems (x_{b1}, y_{b1}), (x_{b2}, y_{b2}), (x_{b3}, y_{b3}), . . . , (x_{bn}, y_{bn}) to calculate matching displacements (eₓ₁, e_{y1}), (eₓ₂, e_{y2}), (eₓ₃, e_{y3}), . . . , (eₓₙ, e_{yn}). After calculation, the displacement calculator 320 generates a measurement value table in which respective combinations of the design coordinate systems (x_{D1}, y_{D1}), (x_{D2}, y_{D2}), (x_{D3}, y_{D3}), (x_{Dn}, y_{Dn}) and the matching displacements (eₓ₁, e_{y1}), (eₓ₂, e_{y2}), (eₓ₃, e_{y3}), . . . , (eₓₙ, e_{yn}) are described. One example of the measurement value table is shown in FIG. 7. The displacement calculator 320 shown in FIG. 1 stores the generated measurement value table in the measurement value memory 204.

(e) At a step S101, the correction manager 321 shown in FIG. 1 reads out a specification of the second exposure apparatus 3b from the specification memory 207, and generates a parameter master which records whether each of the parameters k₁, k₂, k₃, . . . , k₂₀ is “available” or “unavailable” for correction of the second exposure apparatus 3b depicted in FIGS. 1 and 2. One example of such parameter master is shown in FIG. 8. The correction manager shown in FIG. 1 stores the generated parameter master in the parameter memory 202.

(f) At a step S102, the correction manager 321 shown in FIG. 1 reads a specification of the second exposure apparatus 3b depicted in FIGS. 1 and 2 from the specification memory 207 to read an upper limit value and a lower limit value of each of the parameters k₁, k₂, k₃, . . . , k₂₀ which are determined in driving enabled ranges of the reticle stage driver 97, the reticle movable shafts 83a and 83b, the lens drivers 24a and 24b shown in FIG. 3, the wafer stage driver 94 depicted in FIG. 2, the wafer movable shafts 93a and 93b and others. Then, the correction manager 321 depicted in FIG. 1 generates the effective range master shown in FIG. 9 which records the upper limit value and the lower limit value of each of the parameters k₁, k₂, k₃, . . . , k₂₀. The correction manager 321 shown in FIG. 1 stores the generated effective range master in the effective range memory 201. It is to be noted that an upper limit value and a lower limit value of a parameter which cannot be used for correction of the second exposure apparatus 3b are not recorded.

(g) At a step S103, the initializer 301 shown in FIG. 1 generates the working table depicted in FIG. 10 in which the “estimator” of each of the parameter k₁, k₂, k₃, . . . , k₂₀ is initialized to zero, and stores this table in the working value memory 205. Further, the initializer 301 shown in FIG. 1 generates the summery table depicted in FIG. 11 in which the “corrected value” of each of the parameters k₁, k₂, k₃, . . . , k₂₀ is initialized to zero, and stores the summary table in the estimator memory 206. At a step S104, the initializer shown in FIG. 1 reads the parameter master depicted in FIG. 8, and generates the flag table depicted in FIG. 12 in which the “enabled” flag is given to a parameter having the “available” flag in the parameters k₁, k₂, k₃, . . . , k₂₀ and the “disabled” flag is given to a parameter having the “unavailable” flag in the same. The initializer 301 shown in FIG. 1 stores the generated flag table in the flag memory 203.

(h) At a step S200, the approximator 322 reads the respective combinations of the plurality of design coordinate systems (x_{D1}, y_{D1}), (x_{D2}, y_{D2}), (x_{D3}, y_{D3}), . . . , (x_{Dn}, y_{Dn}) and the matching displacements (eₓ₁, e_{y1}), (eₓ₂, e_{y2}), (eₓ₃, e_{y3}), . . . , (eₓₙ, e_{yn}) from the measurement value table shown in FIG. 7. Furthermore, the approximator 322 reads the parameters having the “enabled” flag in the parameters k₁, k₂, k₃, . . . , k₂₀ from the flag table depicted in FIG. 12. Then, the approximator 322 uses the parameters having the “enabled” flag to approximate a relationship between the design coordinate systems (x_{D1}, y_{D1}), (x_{D2}, y_{D2}), (x_{D3}, y_{D3}), . . . , (x_{Dn}, y_{Dn}) and the matching displacements (eₓ₁, e_{y1}), (eₓ₂, e_{y2}), (eₓ₃, e_{y3}), . . . , (eₓₙ, e_{yn}) based on Expressions (3) and (4). Subsequently, the approximator 322 registers in the working table depicted in FIG. 10 the estimator allocated to each of the parameters k₁, k₂, k₃, . . . , k₂₀ by approximating the relationship.

(i) At a step S201, the rounder 325 shown in FIG. 1 judges whether a value of the “estimator” of each of the parameters k₁, k₂, k₃, . . . , k₂₀ falls within the effective range which is not smaller than the “upper limit value” and not greater than the “lower limit value” registered in the effective range master depicted in FIG. 9. When an ineffective value which does not fall within the effective range exists in the values of the “estimators” of the respective parameters k₁, k₂, k₃, . . . , k₂₀, the control advances to a step S202. When all the values of the “estimators” of the respective parameters k₁, k₂, k₃, . . . , k₂₀ are effective values which fall within the effective range, the control proceeds to a step S301.

(j) At the step S202, the rounder 325 shown in FIG. 1 judges whether all the values of the “estimators” of the respective parameters k₁, k₂, k₃, . . . , k₂₀ are ineffective values. When an estimator having an effective value exists in the values of the “estimators” of the respective parameters k₁, k₂, k₃, . . . , k₂₀, the control advances to a step S203. When all the values of the “estimators” of the respective parameters k₁, k₂, k₃, . . . , k₂₀ are ineffective values, the processing is abnormally terminated.

(k) At the step S203, the rounder 325 retrieves a parameter whose “estimator” has an ineffective value from the parameters k₁, k₂, k₃, . . . , k₂₀ registered in the working table depicted in FIG. 10. At a step S204, when the value of the “estimator” is larger than the “upper limit value”, the rounder 325 shown in FIG. 1 rounds the value to the “upper limit value” and re-registers the rounded value as the “estimator” in the working table depicted in FIG. 10. Moreover, when the value of the “estimator” is smaller than the “lower limit value”, the rounder 325 shown in FIG. 1 rounds the value to the “lower limit value” and re-registers the rounded value as the “estimator” in the working table depicted in FIG. 10.

(I) At a step S205, the back-calculator 324 shown in FIG. 1 assigns the “estimators” of the respective parameters k₁, k₂, k₃, . . . , k₂₀ registered in the working table depicted in FIG. 10 to Expressions (3) and (4) stored in the approximate function memory 210 illustrated in FIG. 1. Then, the back-calculator 324 shown in FIG. 1 reads the design coordinate systems (x_{D1}, y_{D1}), (x_{D2}, y_{D2}), (x_{D3}, y_{D3}), . . . , (x_{Dn}, y_{Dn}) from the measurement value table depicted in FIG. 7. The back-calculator 324 shown in FIG. 1 assigns the respective design coordinate systems (x_{D1}, y_{D1}), (x_{D2}, y_{D2}), (x_{D3}, y_{D3}), . . . , (x_{Dn}, y_{Dn}) to Expressions (3) and (4) to calculate back the calculation deviances (hₓ₁, h_{y1}), (hₓ₂, h_{y2}), (hₓ₃, h_{y3}), . . . , (hₓₙ, h_{yn}). At a step S206, the residual calculator 327 subtracts the calculation deviances (hₓ₁, h_{y1}), (hₓ₂, h_{y2}), (hₓ₃, h_{y3}), . . . , (hₓₙ, h_{yn}) from the matching displacements (eₓ₁, e_{y1}), (eₓ₂, e_{y2}), (eₓ₃, e_{y3}), . . . , (eₓₙ, e_{yn}) registered in the measurement value table depicted in FIG. 7, respectively.

(m) At a step S207, the adder 303 shown in FIG. 1 adds the “estimators” of the parameters k₁, k₂, k₃, . . . , k₂₀ registered in the working table depicted in FIG. 10 to the “corrected values” of the parameters k₁, k₂, k₃, . . . , k₂₀ registered in the summary table illustrated in FIG. 11, respectively. At a step S208, the resetter 329 shown in FIG. 1 subtracts the “estimators” of the parameters k₁, k₂, k₃, . . . , k₂₀ from the “upper limit values” of the parameters k₁, k₂, k₃, . . . , k₂₀ registered in the effective range master depicted in FIG. 9, respectively. Likewise, the resetter 329 subtracts the “estimators” of the parameters k₁, k₂, k₃, . . . , k₂₀ from the “lower limit values” of the parameters k₁, k₂, k₃, . . . , k₂₀, respectively.

(n) At a step S209, the resetter 329 shown in FIG. 1 initializes the “estimators” of the respective parameters k₁, k₂, k₃, . . . , k₂₀ registered in the working table depicted in FIG. 10 to zero. At a step S210, the resetter 329 shown in FIG. 1 changes the flag of a parameter whose “estimator” has been rounded at the step S204 in the parameters k₁, k₂, k₃, . . . , k₂₀ from the “enabled” state to the “disabled” state, the flag being stored in the flag table depicted in FIG. 12. Then, the control returns to the step S200.

(o) At a step S301, the adder 303 shown in FIG. 1 adds the “estimators” of the parameters k₁, k₂, k₃, . . . , k₂₀ registered in the working table shown in FIG. 10 to the “corrected values” of the parameters k₁, k₂, k₃, . . . , k₂₀ registered in the summary table illustrated in FIG. 11, respectively. At this time, each of the “corrected values” of the parameters k₁, k₂, k₃, . . . , k₂₀ is a sum total of each of the “estimators” of the parameters k₁, k₂, k₃, . . . , k₂₀ which are calculated every time the steps S200 to S210 are repeated.

(p) At a step S302, the control unit 151 shown in FIG. 1 reads the “corrected values” of the respective parameters k₁, k₂, k₃, . . . , k₂₀ registered in the summary table depicted in FIG. 11. Then, the control unit 151 shown in FIG. 1 uses each of the “corrected values” of the parameters k₁, k₂, k₃, . . . , k₂₀ to correct the second exposure apparatus 3b, and reduces the “matching displacements” from the subsequent exposure. Specifically, the reticle stage driver 97, the reticle movable shafts 83a and 83b, the lens drivers 24a and 24b shown in FIG. 3, the wafer stage driver 94 depicted in FIG. 2, the wafer movable shafts 93a and 93b and others are driven based on the “corrected values” of the respective k₁, k₂, k₃, . . . , k₂₀ to reduce the “matching displacements” from the subsequent exposure, thereby terminating the exposure apparatus correcting method according to the embodiment.

As described above, according to the exposure apparatus correction system and the exposure apparatus correcting method respectively shown in FIGS. 1 and 13, the “matching displacements” based on the inter-apparatus errors of the first exposure apparatus 3a and the second exposure apparatus 3b can be effectively reduced. Usually, the driving range of the lens drivers 24a and 24b shown in FIG. 3 is extremely narrower than the driving ranges of the reticle stage driver 97, the reticle movable shafts 83a and 83b, the wafer stage driver 94, the wafer movable shafts 93a and 93b and others shown in FIG. 2. Therefore, as compared with the parameters k₁ to k₆ concerning lower-order terms in Expressions (3) and (4), the effective range of each of the parameters k₇ to k₂₀ concerning higher-order terms is restricted to a narrow range. Therefore, when the “estimator” of any of the parameters k₇ to k₂₀ calculated at the step S200 is out of the effective range, this value must be rounded to fall within the effective range at the step S204. However, a residual of the “estimator” before and after rounding leads to a correction error. The correction error appears as a residual obtained when each of the calculation deviances (hₓ₁, h_{y1}), (hₓ₂, h_{y2}), (hₓ₃, h_{y3}), . . . , (hₓₙ, h_{yn}) is subtracted from each of the matching displacements (eₓ₁, e_{y1}), (eₓ₂, e_{y2}), (eₓ₃, e_{y3}), . . . , (eₓₙ, e_{yn}). On the contrary, according to the embodiment, repeating the steps S201 to S210 can change the “estimator” of a parameter which has not been rounded within the effective range to reduce the correction error. Therefore, according to the exposure apparatus correction system and the exposure apparatus correcting method of the embodiment, the effective range of each of the plurality of drivers included in the second exposure apparatus 3b, e.g., the reticle stage driver 97, the reticle movable shafts 83a and 83b, the wafer stage driver 94 and the wafer movable shafts 93a and 93b shown in FIG. 2 and the lens drivers 24a and 24b and others shown in FIG. 3 can be effectively exploited to usefully reduce the “matching displacements”, and a side effect such as defocusing or a fluctuation in aberration can be suppressed.

It is to be noted that the inter-apparatus error of the two exposure apparatuses, i.e., the first exposure apparatus 3a and the second exposure apparatus 3b is corrected in the embodiment. On the other hand, it is possible to reduce each “matching displacement” produced in the same exposure apparatus with time, for example. In this case, it is good enough to carry out the exposure apparatus correcting method shown in FIG. 13 on the assumption that the first exposure apparatus and the second exposure apparatus are the same exposure apparatus.

Additionally, at the steps S91 to S92, after each of the first inspection patterns 45a to 15n is transferred onto the first inspection resist on the first inspection wafer 15, each of the second inspection patterns 145a to 145n may be transferred onto the first inspection resist, and thereafter the first inspection resist may be subjected to post exposure bake (PEB) processing and development processing. That is, the first inspection wafer and the second inspection wafer may be the same. Further, although the matching displacements (eₓ₁, e_{y1}), (eₓ₂, e_{y2}), (eₓ₃, e_{y3}), . . . , (eₓₙ, e_{yn}) calculated at the step S100 are directly used in the embodiment, the first transfer process at the step S91 and the second transfer process at the step S92 may be respectively repeated more than once, and the averaged matching displacements may be utilized for the subsequent calculation.

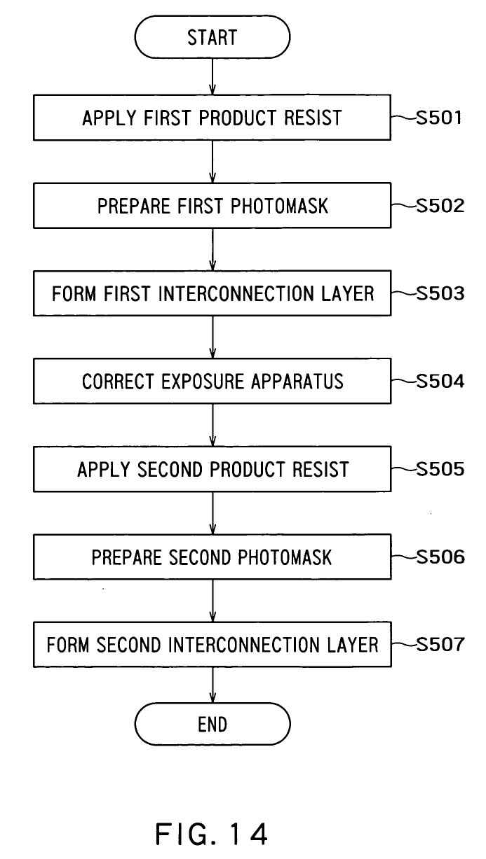

A manufacturing method of a semiconductor device according to an embodiment will now be described with reference to a flowchart of FIG. 14.

(A) At a step S501, a product wafer is prepared as a processing target substrate, and the processing target substrate is spin-coated with a first product resist. Here, an Si wafer or the like can be used as the product wafer, and a photoresist or the like can be utilized as the first product resist. At a step S502, the product wafer is arranged on a wafer stage 32 depicted in FIG. 2 in a first exposure apparatus 3a. Furthermore, a first photomask having a first interconnection pattern of a semiconductor integrated circuit is arranged on a reticle stage 51.

(B) At a step S503, illumination light is emitted from an illumination light source 41, and the first interconnection pattern is transferred onto the first product resist. Then, the first product resist is subjected to PEB processing and development processing, whereby a first resist pattern corresponding to the first interconnection patter is processed on the first product resist. Then, an electroconductive film formed of, e.g., copper (Cu) is deposited on the first product wafer with the first resist pattern being used as a mask, and a first interconnection layer having the first interconnection patter is formed on the processing target substrate, thereby configuring a new processing target substrate. That is, the “processing target substrate” varies to the “new processing target substrate” as needed with progress of manufacturing steps, and it is defined as a substrate which is subjected to current target processing. An insulating layer using an inorganic insulating material such as silicon dioxide (SiO₂) or silicon monoxide (SiOC, SiOF) having carbon or fluorine added thereto is deposited on the first interconnection layer.

(C) At a step S504, an inter-apparatus error between the first exposure apparatus 3a and the second exposure apparatus 3b shown in FIG. 1 is corrected by the same method as the steps S90 to S302 depicted in FIG. 13. At a step S505, the insulating layer of the processing target substrate is spin-coated with a second product resist. Here, a photoresist or the like can be used as the second product resist like the first product resist. At a step S506, the second product resist is arranged on the wafer stage 32 shown in FIG. 2 in the second exposure apparatus 3b. Moreover, a second photomask having a second interconnection pattern of the semiconductor integrated circuit is arranged on the reticle stage 51.

(D) At a step S507, illumination light is emitted from the illumination light source 41, and the first interconnection pattern is positioned on the second product resist to transfer the second interconnection pattern. Then, the second product resist is subjected to PEB processing and development processing, whereby a second resist pattern corresponding to the second interconnection pattern is processed on the second product resist. Subsequently, an electroconductive film formed of, e.g., copper (Cu) is deposited from an upper side of the second resist pattern to form a second interconnection layer having the second interconnection pattern on the first interconnection layer, thereby constituting a new processing target substrate. Thereafter, formation of the insulating layer and the interconnection layer on the processing target substrate is repeated, thus terminating the manufacturing method of the semiconductor device according to the embodiment.

As described above, according to the manufacturing method of the semiconductor device of the embodiment shown in FIG. 14, it is possible to reduce each “matching displacement” of the first interconnection pattern and the second interconnection pattern based on an inter-apparatus error between the first exposure apparatus 3a and the second exposure apparatus 3b depicted in FIG. 1. Therefore, the semiconductor device can be manufactured with high accuracy, and a yield ratio can be also improved. Additionally, an arbitrary exposure apparatus can be selected from a plurality of exposure apparatuses to correct an inter-apparatus error with respect to an exposure apparatus on which the first interconnection pattern has been transferred. Therefore, an operating ratio of each of the plurality of exposure apparatuses at a production site can be improved, thereby enhancing production efficiency of the semiconductor device.

Although the above has described some of embodiments according to the present invention, it should not be understood that the description and the drawings forming a part of this disclosure do not restrict the present invention. Various alternative modes, embodiments and operating technologies will be apparent to persons skilled in the art based on this disclosure. For example, the above-described exposure apparatus correcting method can be realized as a series of processing or operations which are continuous in time series. Therefore, in order to execute the exposure apparatus correcting method in the exposure apparatus correction system depicted in FIG. 1, the exposure apparatus correcting method shown in FIG. 13 can be realized by a computer program product which specifies a plurality of functions exercised by a processor or the like in the CPU 300. Here, the computer program product means a recording medium, a recording unit or the like which can be input/output with respect to a computer system. The recording medium includes a memory unit, a magnetic disk unit, an optical disk unit, and any other unit which can record a program. As mentioned above, it is needless to say that the present invention includes various embodiments which are not described herein.

What is claimed is:

1. An exposure apparatus correction system comprising:
a displacement calculator which calculates matching displacements between a first inspection pattern and a second inspection pattern, the first inspection pattern being transferred by an external first exposure apparatus, the second inspection pattern being positioned with respect to the first inspection pattern and transferred by a second exposure apparatus;
an approximator which applies design coordinate systems and values of the calculated matching displacements to approximate expressions in which the matching displacements and a relationship between coordinate systems including the second inspection pattern is approximated by using a plurality of parameters, thereby allocating estimators to the plurality of respective parameters, the plurality of parameters having a mutually complementary relationship;
a rounder which rounds estimators of the allocated estimators which are out of an effective range restricted by the second exposure apparatus to fall within the effective range;
a back-calculator which defines the rounded estimators as new estimators and applies the new estimators and the design coordinate systems to the approximate expressions to calculate back calculation deviances which are expected to occur between the first inspection pattern and the second inspection pattern when the rounded values are used;
a residual calculator which subtracts the calculation deviances from the matching displacements to obtain residuals;
a corrected value calculator which utilizes the mutually complementary relationship between the plurality of parameters to calculate corrected values as values which reduce the residuals based on other parameters than the parameters whose estimators have been rounded in the plurality of parameters with respect to the other parameters;
an adder which sequentially adds the new estimators and the corrected values and outputs results as a sum total of the estimators;
an estimator memory which stores the sum total of the estimators; and
a controller which allows the rounder, the back-calculator, the residual calculator, the corrected value calculator and the adder to cyclically perform repeated operations, and corrects the second exposure apparatus based on the sum total of the estimators stored in the estimator memory.

2. The exposure apparatus correction system according to claim 1,
wherein the controller allows the rounder, the back-calculator, the residual calculator, the corrected value calculator and the adder to perform repeated operations until the estimators which are out of the effective range no longer exist, and corrects the second exposure apparatus based on the sum total of the estimators stored in the estimator memory when the estimators which are out of the effective range no longer exist.

3. The exposure apparatus correction system according to claim 1,
wherein the first exposure apparatus and the second exposure apparatus are the same apparatus, and
the matching displacements are generated due to variations with time.

4. The exposure apparatus correction system according to claim 1,
wherein the first inspection pattern and the second inspection pattern are formed on the same processing target substrate and the matching displacement is produced with time.

5. The exposure apparatus correction system according to claim 1,
wherein the displacement calculator calculates the matching displacements between the first inspection pattern and the second inspection pattern more than once, and outputs averaged values as the matching displacements.

6. The exposure apparatus correction system according to claim 1, including a measurement apparatus which measures the first inspection pattern and the second inspection pattern,
wherein the measurement apparatus is one of an optical microscope, a scanning electron microscope and an atom force microscope.

7. An exposure apparatus correcting method comprising:
calculating matching displacements between a first inspection pattern and a second inspection pattern, the first inspection pattern being transferred by a first exposure apparatus with design coordinate systems on a first inspection wafer being determined as targets, the second inspection pattern being positioned with respect to the first inspection pattern and transferred by a second exposure apparatus with the design coordinate systems on a second inspection wafer being determined as targets;
applying the design coordinate systems and values of the calculated matching displacements to approximate expressions in which a relationship between the matching displacements and coordinate systems including the second inspection pattern is approximated by using a plurality of parameters to allocate estimators to the plurality of parameters, the plurality of parameters having a mutually complementary relationship;
rounding estimators of the allocated estimators which are out of an effective range restricted by the second exposure apparatus to fall within the effective range;
defining the rounded estimators as new estimators and applying the new estimators and the design coordinate systems to the approximate expressions to calculate back calculation deviances which are expected to occur between the first inspection pattern and the second inspection pattern when the rounded values are used;
subtracting the calculation deviances from the matching displacements to obtain residuals;
utilizing the mutually complementary relationship between the plurality of parameters to calculate corrected values as values which reduce the residuals based on other parameters than the parameters whose estimators have been rounded with respect to the other parameters;
sequentially adding the new estimators and the corrected values and outputting a result as a sum total of the estimators; and
repeating the rounding, the back calculation, the calculation of the residuals, the calculation of the corrected values and the sequential addition to correct the second exposure apparatus based on the sum total of the estimators.

8. The exposure apparatus correcting method according to claim 7,
wherein the rounding, the back calculation, the calculation of the residuals, the calculation of the corrected values and the sequential addition are repeated until the estimators which are out of the effective range no longer exist, and
the second exposure apparatus is corrected based on the sum total of the estimators when the estimators which are out of the effective range no longer exist.

9. The exposure apparatus correcting method according to claim 7,
wherein the first exposure apparatus and the second exposure apparatus are the same apparatus, and
the matching displacements are generated due to variations with time.

10. The exposure apparatus correcting method according to claim 7,
wherein the first inspection pattern and the second inspection pattern are formed on the same processing target substrate and the matching displacement is produced with time.

11. The exposure apparatus correcting method according to claim 7,
wherein the calculation of the matching displacements includes calculating the matching displacements between the first inspection pattern and the second inspection pattern more than once and averaging the calculated matching displacements.

12. The exposure apparatus correcting method according to claim 7,
wherein the calculation of the matching displacements includes measuring the first inspection pattern and the second inspection pattern by using an electromagnetic wave or an atomic force.

13. A manufacturing method of a semiconductor device, comprising:
coating a processing target substrate with a first resist;
transferring a first product pattern onto the first resist by using a first exposure apparatus;
processing the processing target substrate with the first product pattern being used as a mask;
calculating matching displacements between the first inspection pattern and the second inspection pattern, the first inspection pattern being transferred by the first exposure apparatus with design coordinate systems on a first inspection wafer being determined as targets, the second inspection pattern being positioned with respect to the first inspection pattern and transferred by a second exposure apparatus with the design coordinate systems on a second inspection wafer being determined as targets;
applying the design coordinate systems and values of the calculated matching displacements to approximate expressions in which a relationship between the matching displacements and coordinate systems including the second inspection pattern is approximated by using a plurality of parameters to allocate estimators to the plurality of parameters, the plurality of parameters having a mutually complementary relationship;
rounding estimators of the allocated estimators which are out of an effective range restricted by the second exposure apparatus to fall within the effective range;
defining the rounded estimators as new estimators and applying the new estimators and the design coordinate systems to the approximate expressions to calculate back calculation deviances which are expected to occur between the first inspection pattern and the second inspection pattern when the rounded values are used;
subtracting the calculation deviances from the matching displacements to obtain residuals;
utilizing the mutually complementary relationship between the plurality of parameters to calculate corrected values as values which reduce the residuals based on other parameters than the parameters whose estimators have been rounded with respect to the other parameters;
sequentially adding the new estimators and the corrected values and outputting a result as a sum total of the estimators;
repeating the rounding, the back calculation, the calculation of the residuals, the calculation of the corrected values, and the sequentially addition to correct the second exposure apparatus based on the sum total of the estimators;
coating the processing target substrate with a second resist;
positioning a second product pattern with respect to the first product pattern and transferring the same onto the second resist by using the corrected second exposure apparatus; and
processing the processing target substrate with the second product pattern being used as a mask.

14. The manufacturing method of a semiconductor device according to claim 13,
wherein the rounding, the back calculation, the calculation of the residuals, the calculation of the corrected values and the sequential addition are repeated until the estimators which are out of the effective range no longer exist, and
the second exposure apparatus is corrected based on the sum total of the estimators when the estimators which are out of the effective range no longer exist.

15. The manufacturing method of a semiconductor device according to claim 13,
wherein the first exposure apparatus and the second exposure apparatus are the same apparatus, and
the matching displacements are generated due to variations with time.

16. The manufacturing method of a semiconductor device according to claim 13,
wherein the first inspection wafer and the second inspection wafer are the same inspection wafer.

17. The manufacturing method of a semiconductor device according to claim 13,
wherein the calculation of the matching displacements includes calculating the matching displacements between the first inspection pattern and the second inspection pattern more than once and averaging the calculated matching displacements.

18. The manufacturing method of a semiconductor device according to claim 13,
wherein the calculation of the matching displacements includes measuring the first inspection pattern and the second inspection pattern in use of one of an optical microscope, a scanning electron microscope and an atom force microscope.
